(19) United States
(12) Patent Application Publication
(10) Pub. No.: US 2017/0221930 A1
(43) Pub. Date: Aug. 3, 2017

(54) THIN FILM TRANSISTOR ARRAY SUBSTRATE AND METHOD FOR MANUFACTURING THE SAME

(71) Applicant: Shenzhen China Star Optoelectronics Technology Co. , Ltd., Shenzhen, Guangdong (CN)

(72) Inventor: Zhichao ZHOU, Shenzhen, Guangdong (CN)

(73) Assignee: Shenzhen China Star Optoelectronics Technology Co. , Ltd., Shenzhen, Guangdong (CN)

(21) Appl. No.: 15/317,296

(22) PCT Filed: Jun. 3, 2016
(86) PCT No.: PCT/CN2016/084752

§ 371 Date: Dec. 8, 2016

(30) Foreign Application Priority Data
Jan. 28, 2016 (CN) 201610058366.3

(51) Int. Cl. H01L 27/12; H01L 21/4763; H01L 29/423; H01L 29/66; H01L 29/24; H01L 29/786; H01L 21/441; H01L 21/02

(52) U.S. Cl. CPC H01L 27/1225; H01L 21/441; H01L 21/47635; H01L 21/02565; H01L 29/66969; H01L 29/24; H01L 29/7869; H01L 27/1288; H01L 29/42356; G02F 1/1368

(57) ABSTRACT

A thin film transistor array substrate, a method for manufacturing the same and a liquid crystal panel are provided. The film transistor array substrate has a transparent substrate formed with a gate electrode, a gate insulating layer, a semiconductor layer, an etching stop layer, a source electrode, a drain electrode, and a pixel electrode. Through using the MoTi electrode to replace the conventional ITO electrode in the film transistor array substrate, the PV layer can be simultaneously omitted in the manufacturing process of the film transistor array substrate for reducing one of the masks, lowering the manufacturing costs, and expanding the application of the IGZO structure.

### FIELD OF THE INVENTION

The present invention relates to a thin film transistor and method for manufacturing the same, and more particularly to a thin film transistor array substrate and method for manufacturing the same.

### BACKGROUND OF THE INVENTION

Liquid crystal displays are currently most widely used as flat panel displays, which have gradually become used in a variety of electronic devices, such as mobile phones, personal digital assistants (PDA), digital cameras, computer screens or notebook screens, and are widely applied in displays with high-resolution color screens. With the development of liquid crystal display technology, the user's quality requirements for the liquid crystal display, such as exterior design, are increasing.

A liquid crystal panel is a main component of the liquid crystal display, which includes a vacuum laminating thin film transistor (TFT) array substrate, a color filter (CF) substrate, and a liquid crystal layer and an alignment film disposed therebetween.

With the large-size of the current displays, the demands for high-resolution are getting higher and higher. Therefore, a requirement in charge and discharge of the semiconductor device is increasing. Indium gallium zinc oxide (IGZO) materials can have characteristics of high mobility rate, high switch on state current, low switch off state current, quickly switching, etc., therefore, they can effectively meet the requirements of highly charging and discharging.

Although an Etching Stop structure device comprise a protective layer in currently used IGZO structures, the stability of electrical properties are often better than other structures. However, due to adding a mask, the preparation cost of the structure is high and limits the application of IGZO.

Thus, it is necessary to provide a thin film transistor array substrate and a liquid crystal display device applying the same to solve the problems of the prior art.

### SUMMARY OF THE INVENTION

A first object of the present invention is to provide a method for manufacturing a thin film transistor array substrate, which comprises: step S10: providing a transparent substrate, depositing a first metal layer on the transparent substrate, and patterning the first metal layer for forming a gate electrode pattern; step S20: depositing a gate insulating layer on the gate electrode pattern and the transparent substrate; step S30: depositing a semiconductor layer on the gate insulating layer, patterning the semiconductor layer for forming a semiconductor layer pattern; wherein the semiconductor layer pattern corresponds to the gate electrode pattern and the semiconductor layer is made of indium gallium zinc oxide; step S40: depositing an etching stop layer on the semiconductor layer pattern and the gate insulating layer, forming at least two contact holes spaced apart from each other within a region of the etching stop layer corresponding to the semiconductor layer, to expose the semiconductor layer; step S50: depositing a second metal layer on the etching stop layer, patterning the second metal layer for forming a source electrode and a drain electrode, wherein the source electrode and the drain electrode are connected with the semiconductor layer through the contact holes, respectively; and step S60: depositing a pixel electrode pattern on the source electrode and the drain electrode, wherein the pixel electrode is made of a molybdenum alloy which is made of molybdenum and one of the group consisting of titanium, tantalum, chromium, nickel, indium and aluminum.

In the embodiment of the present invention, the molybdenum alloy is a molybdenum titanium alloy.

A second object of the present invention is to provide a thin film transistor array substrate having a transparent substrate. The thin film transistor array substrate further comprises: a gate electrode deposited on the transparent substrate; a gate insulating layer disposed on the transparent substrate and covering the gate electrode; a semiconductor layer disposed on the gate insulating layer, and corresponding to the gate electrode on the transparent substrate; an etching stop layer disposed on the gate insulating layer and covering the semiconductor layer, and a plurality of contact holes formed onto the etching stop layer; a source electrode and a drain electrode disposed on the etching stop layer and connected with the semiconductor layer through the contact hole, respectively; and a pixel electrode disposed on the source electrode and the drain electrode.

In the embodiment of the present invention, the semiconductor layer is made of indium gallium zinc oxide (IGZO).

In the embodiment of the present invention, the pixel electrode is made of molybdenum alloy. Preferably, the molybdenum alloy is made of molybdenum (Mo) and one of the group consisting of titanium (Ti), tantalum (Ta), chromium (Cr), nickel (Ni), indium (In) and aluminum (Al). More preferably, the molybdenum alloy is a molybdenum titanium alloy (MoTi).

The present invention further provides a method for manufacturing a thin film transistor array substrate as above. The method comprises: step S10: providing a transparent substrate, depositing a first metal layer on the transparent substrate, and patterning the first metal layer for forming a gate electrode pattern; step S20: depositing a gate insulating layer on the gate electrode pattern and the transparent substrate; step S30: depositing a semiconductor layer on the gate insulating layer, patterning the semiconductor layer for forming a semiconductor layer pattern; wherein the semiconductor layer pattern corresponds to the gate electrode pattern and the semiconductor layer is made of indium gallium zinc oxide; step S40: depositing an etching stop layer on the semiconductor layer pattern and the gate insulating layer, forming at least two contact holes spaced apart from each other within a region of the etching stop layer corresponding to the semiconductor layer, to expose the semiconductor layer; step S50: depositing a second metal layer on the etching stop layer, patterning the second metal layer for forming a source electrode and a drain electrode, wherein the source electrode and the drain electrode are connected with the semiconductor layer through the contact holes, respectively; and step S60: depositing a pixel electrode pattern on the source electrode and the drain electrode.

The present invention further provides a liquid crystal panel, which comprises a first substrate and a second substrate which are relatively arranged with each other, liquid crystal compositions and an alignment film filled between the first substrate and the second substrate, wherein the first substrate is the thin film transistor array substrate mentioned above, the second substrate is a color filter substrate.

In the thin film transistor array substrate of the present invention, the MoTi electrode replaces the conventional electrode structure of ITO electrode, thereby acting as a pixel electrode while covering and protecting the source electrode and the drain electrode located under the MoTi electrode and acting similar to a passivation layer (PV layer). Accordingly, in the method for manufacturing the thin film transistor array substrate of the present invention, the PV layer can be omitted for omitting a mask and further for lowering the manufacturing costs and expanding the application of IGZO structure.

### DESCRIPTION OF THE DRAWINGS

FIG. 1 is a structural schematic view of a thin film transistor array substrate in a pixel structure of the present invention;

FIG. 2 is a procedure of the thin film transistor array substrate of the present invention;

FIGS. 3A-3F are flow charts of manufacturing the thin film transistor array substrate of the present invention; and

FIG. 4 is a structural schematic view of the pixel structure of the liquid crystal panel comprising the thin film transistor array substrate of the present invention.

### DETAILED DESCRIPTION OF THE PREFERRED EMBODIMENTS

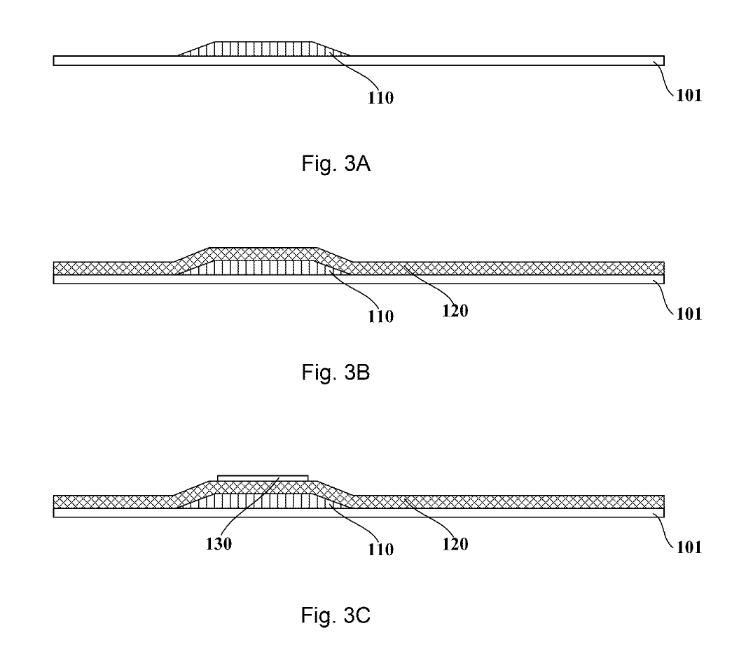

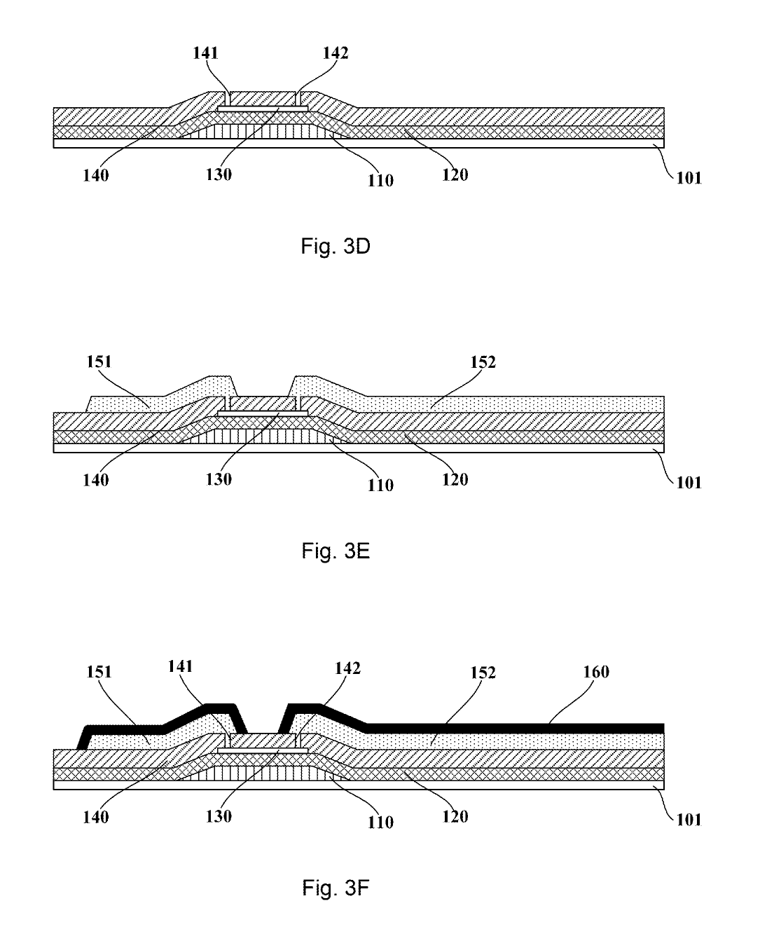

This description of the exemplary embodiments is intended to be read in connection with the accompanying drawings, which are to be considered part of the entire written description. In the description, terms such as “lower”, “upper”, “horizontal”, “vertical”, “above”, “below”, “up”, “down”, “top”, and “bottom”, as well as derivatives thereof should be construed to refer to the orientation as then described or as shown in the drawing under discussion. These terms are for convenience of description and do not require that the apparatus be constructed or operated in a particular orientation, and do not limit the scope of the invention. Referring to the drawings of the present invention, the same symbol represents the same component. It should be noted that FIGS. 3A-3F are presented in a simplified exemplary manner for convenience description. Besides, the circuit amount is simplified and portions unnecessary to an understanding of the invention are omitted for clarity.

The preferred embodiment of the present invention provides a thin film transistor array substrate 100. The thin film transistor array substrate 100 comprises a transparent substrate 101. The following description takes a pixel region as an exemplary embodiment for describing the thin film transistor array substrate of the present invention in detail.

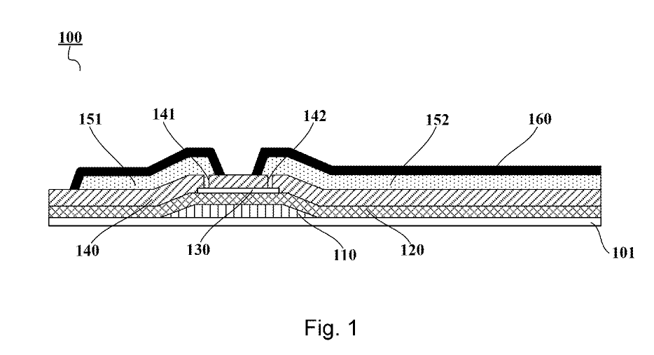

Referring to FIG. 1, the thin film transistor array substrate 100 comprises: a gate electrode 110, a gate insulating layer 120, a semiconductor layer 130, an etching stop layer 140, a source electrode 151, a drain electrode 152, and a pixel electrode 160. As shown in FIG. 1, the specific structure of the thin film transistor array substrate 100 successively comprises: the transparent substrate 101; the gate electrode 110 deposited on the transparent substrate 101; the gate insulating layer 120 disposed on the transparent substrate and covering the gate electrode; the semiconductor layer 130 disposed on the gate insulating layer 120, and corresponding to the gate electrode 110 on the transparent substrate 101; the etching stop layer 140 disposed on the gate insulating layer 120 and covering the semiconductor layer 130. Moreover, as shown in FIG. 1, a plurality of contact holes 141, 142 are formed onto the etching stop layer 140, a source electrode 151 and a drain electrode 152 are disposed on the etching stop layer 140 and are connected with the semiconductor layer 130 through the contact holes 141, 142, respectively and the pixel electrode 160 is disposed on the source electrode 151 and the drain electrode 152. The semiconductor layer is made of indium gallium zinc oxide (IGZO). The molybdenum alloy is a molybdenum titanium alloy (MoTi).

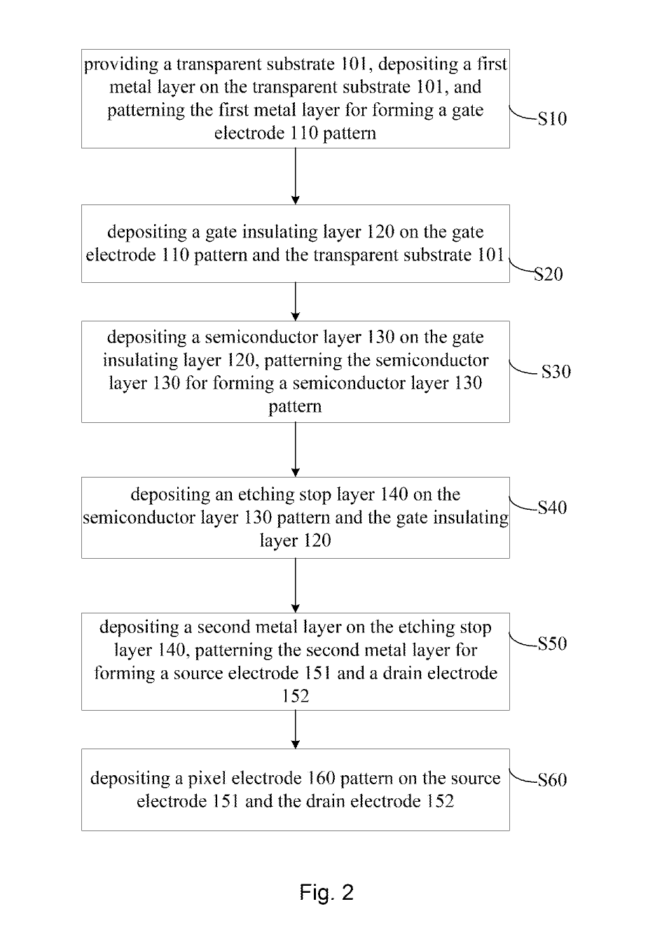

Jointly referring to FIG. 2 and FIGS. 3A-3F, a method for manufacturing the thin film transistor array substrate are described in detail. Referring to FIG. 2 and FIGS. 3A-3F, the present invention further provides a manufacturing method of the thin film transistor array substrate, which comprises the following steps.

Referring to step S10 and FIG. 3A, step S10: providing a transparent substrate 101, depositing a first metal layer on the transparent substrate 101, and patterning the first metal layer for forming a gate electrode 110 pattern.

Referring to step S20 and FIG. 3B, step S20: depositing a gate insulating layer 120 on the gate electrode 110 pattern and the transparent substrate 101.

Referring to step S30 and FIG. 3C, step S30: depositing a semiconductor layer 130 on the gate insulating layer 120, patterning the semiconductor layer 130 for forming a semiconductor layer 130 pattern. The semiconductor layer 130 pattern corresponds to the gate electrode 110 pattern.

Referring to step S40 and FIG. 3D, step S40: depositing an etching stop layer 140 on the semiconductor layer 130 pattern and the gate insulating layer 120, and forming at least two contact holes 141, 142 spaced apart from each other within a region of the etching stop layer 140 corresponding to the semiconductor layer 130, to expose the semiconductor layer 130.

Referring to step S50 and FIG. 3E, step S50: depositing a second metal layer on the etching stop layer 140, patterning the second metal layer for forming a source electrode 151 and a drain electrode 152. The source electrode 151 and the drain electrode 152 are connected with the semiconductor layer 130 through the contact holes 141, 142, respectively.

Referring to step S60 and FIG. 3F, S60: depositing a pixel electrode 160 pattern on the source electrode 151 and the drain electrode 152.

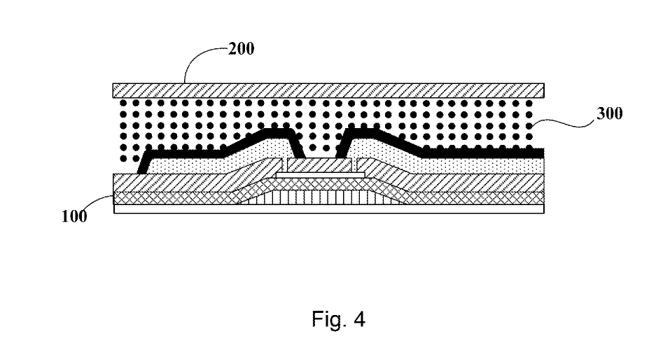

Furthermore, the thin film transistor array substrate can be used in liquid crystal panel. Referring to FIG. 4, which is a structural schematic view of the pixel structure of the liquid crystal panel comprising the thin film transistor array substrate of the present invention. As shown in FIG. 4, the present invention further provides a liquid crystal panel, which comprises the thin film transistor array substrate 100 and a second substrate 200 which are relatively arranged with each other, and liquid crystal compositions 300 filled between the thin film transistor array substrate 100 and the second substrate 200. The second substrate is a color filter substrate.

In the thin film transistor array substrate of the present invention, the MoTi electrode replaces the conventional electrode structure of ITO electrodes, thereby acting as a pixel electrode while covering and protecting the source electrode and the drain electrode located under the MoTi electrode and acting similar to a passivation layer (PV layer). Accordingly, in the method for manufacturing the thin film transistor array substrate of the present invention, the PV layer can be omitted for omitting a mask and further for lowering the manufacturing costs and expanding the application of the IGZO structure.

The present invention has been described with preferred embodiments thereof, and it is understood that many changes and modifications to the described embodiment can be carried out without departing from the scope and the spirit of the invention that is intended to be limited only by the appended claims.

What is claimed is:

1. A method for manufacturing a thin film transistor array substrate, comprising:
a step (S10) of providing a transparent substrate, depositing a first metal layer on the transparent substrate, and patterning the first metal layer for forming a gate electrode pattern;
a step (S20) of depositing a gate insulating layer on the gate electrode pattern and the transparent substrate;
a step (S30) of depositing a semiconductor layer on the gate insulating layer, patterning the semiconductor layer for forming a semiconductor layer pattern; wherein the semiconductor layer pattern corresponds to the gate electrode pattern and the semiconductor layer is made of indium gallium zinc oxide;
a step (S40) of depositing an etching stop layer on the semiconductor layer pattern and the gate insulating layer, forming at least two contact holes spaced apart from each other within a region of the etching stop layer corresponding to the semiconductor layer, to expose the semiconductor layer;
a step (S50) of depositing a second metal layer on the etching stop layer, patterning the second metal layer for forming a source electrode and a drain electrode, wherein the source electrode and the drain electrode are connected with the semiconductor layer through the contact holes, respectively; and
a step (S60) of depositing a pixel electrode pattern on the source electrode and the drain electrode, wherein the pixel electrode is made of a molybdenum alloy which is made of molybdenum and one selected from the group consisting of titanium, tantalum, chromium, nickel, indium and aluminum.

2. The manufacturing method according to claim 1, wherein the molybdenum alloy is a molybdenum titanium alloy.

3. A thin film transistor array substrate having a transparent substrate, the thin film transistor array substrate further comprising:
a gate electrode deposited on the transparent substrate;
a gate insulating layer disposed on the transparent substrate and covering the gate electrode;
a semiconductor layer disposed on the gate insulating layer, and corresponding to the gate electrode on the transparent substrate;
an etching stop layer disposed on the gate insulating layer and covering the semiconductor layer, and a plurality of contact holes formed on the etching stop layer;
a source electrode and a drain electrode disposed on the etching stop layer and connected with the semiconductor layer through the contact holes, respectively; and
a pixel electrode disposed on the source electrode and the drain electrode.

4. The thin film transistor array substrate according to claim 3, wherein the semiconductor layer is made of indium gallium zinc oxide.

5. The thin film transistor array substrate according to claim 4, wherein the pixel electrode is made of a molybdenum alloy.

6. The thin film transistor array substrate according to claim 5, wherein the molybdenum alloy is made of molybdenum and one selected from the group consisting of titanium, tantalum, chromium, nickel, indium and aluminum.

7. The thin film transistor array substrate according to claim 6, wherein the molybdenum alloy is a molybdenum titanium alloy.

8. A method for manufacturing a thin film transistor array substrate according to claim 3, comprising:
a step (S10) of providing a transparent substrate, depositing a first metal layer on the transparent substrate, and patterning the first metal layer for forming a gate electrode pattern;
a step (S20) of depositing a gate insulating layer on the gate electrode pattern and the transparent substrate;
a step (S30) of depositing a semiconductor layer on the gate insulating layer, patterning the semiconductor layer for forming a semiconductor layer pattern; wherein the semiconductor layer pattern corresponds to the gate electrode pattern;
a step (S40) of depositing an etching stop layer on the semiconductor layer pattern and the gate insulating layer, forming at least two contact holes spaced apart from each other within a region of the etching stop layer corresponding to the semiconductor layer, to expose the semiconductor layer;
a step (S50) of depositing a second metal layer on the etching stop layer, patterning the second metal layer for forming a source electrode and a drain electrode, wherein the source electrode and the drain electrode connect with the semiconductor layer through the contact holes, respectively; and
a step (S60) of depositing a pixel electrode pattern on the source electrode and the drain electrode.

9. The method according to claim 8, wherein the semiconductor layer is made of indium gallium zinc oxide.

10. The method according to claim 8, wherein the pixel electrode is made of a molybdenum alloy.

11. The method according to claim 9, wherein the molybdenum alloy is a molybdenum titanium alloy.
